(19) United States
(12) Patent Application Publication
(10) Pub. No.: US 2014/0081590 A1
(43) Pub. Date: Mar. 20, 2014

(54) ELECTRONIC DEVICE AND METHOD FOR MANAGING TEST ITEMS OF AN OBJECT

(71) Applicant: HON HAI PRECISION INDUSTRY CO., LTD., New Taipei (TW)

(72) Inventor: ZHENG-HENG SUN, New Taipei (TW)

(73) Assignee: HON HAI PRECISION INDUSTRY CO., LTD., New Taipei (TW)

(21) Appl. No.: 14/011,752

(22) Filed: Aug. 27, 2013

(30) Foreign Application Priority Data
Sep. 17, 2012 (CN) 2012103455673

(51) Int. Cl. G01R 31/28; G01R 31/3181

(52) U.S. Cl. CPC G01R 31/2834; G01R 31/3181
USPC 702/122

(57) ABSTRACT

In a method for an electronic device to manage test items of an object, a testing procedure is performed on the test items of the object. When the testing procedure on a test item is finished, the method records test states of the finished test item in a state list. The method further obtains a test result of the finished test item by comparing the state list with a standard list stored in a storage system of the electronic device. When the test state of the finished test item is indicated to be abnormal, the method marks the finished test item with a time index in the state list and displays a failure message and a name of the finished test item with the time index on a display screen of the electronic device.

### BACKGROUND

1. Technical Field

Embodiments of the present disclosure relate to test management technology, and particularly to an electronic device and a method for managing test items of an object.

2. Description of Related Art

During a testing procedure, if test items of an unit under test (UUT) (e.g. an object) indicate failure, a detailed report needs to be provided regarding the failure according to a system event log (SEL) and manual observation of the whole testing procedure.

However, if one test item takes a long time (e.g. one or more days), it is difficult to monitor the whole testing procedure due to the length of time involved. Furthermore, when a test item indicates failure, the failure can only be analyzed by looking at the SEL, without graphical data of the testing procedure. An Internet Protocol (IP) camera or a charge-coupled device (CCD) can be used to record test information. However, reviewing all of the recorded test information to find out the reasons for a single failure is inefficient and inconvenient.

### BRIEF DESCRIPTION OF THE DRAWINGS

FIG. 1 is a schematic diagram of one embodiment of an electronic device including a management system.

FIG. 2 is a block diagram of one embodiment of function modules of the management system in the electronic device in FIG. 1.

FIG. 3A and FIG. 3B are schematic diagrams illustrating one embodiment of images of a state list.

FIG. 4 is a flowchart illustrating one embodiment of a method for managing test items of an object using the electronic device of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean “at least one.”

In general, the word “module,” as used herein, refers to logic embodied in hardware or firmware unit, or to a collection of software instructions, written in a programming language. One or more software instructions in the modules may be embedded in firmware unit, such as in an EPROM. The modules described herein may be implemented as either software and/or hardware modules and may be stored in any type of non-transitory computer-readable medium or other storage device. Some non-limiting examples of non-transitory computer-readable media may include CDs, DVDs, BLU-RAY, flash memory, and hard disk drives.

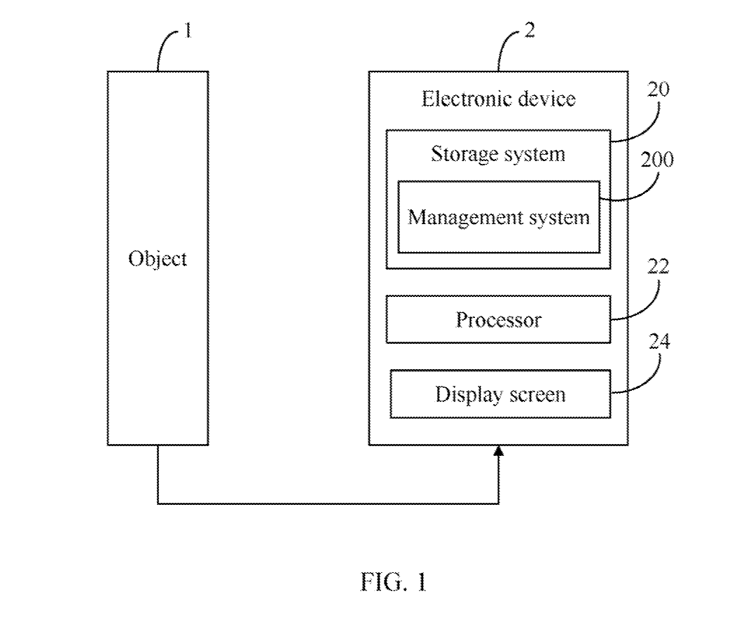

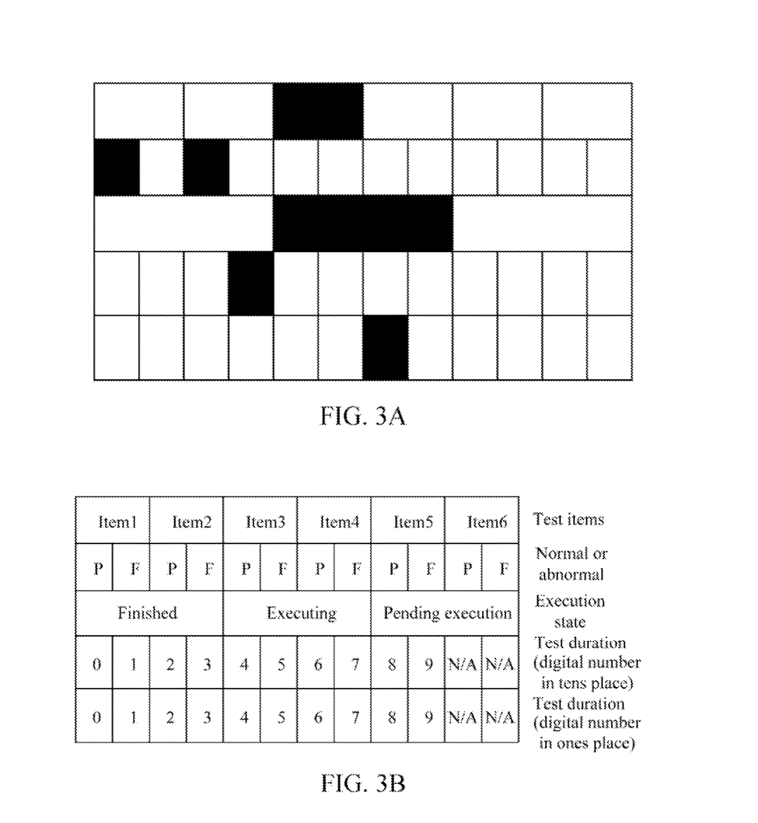

FIG. 1 is a schematic diagram of one embodiment of an electronic device 2 including a management system 200. In the embodiment, the electronic device 2 may be a mobile phone, a notebook computer, a personal digital assistant (PDA), or a computing device, for example. The electronic device 2 performs a testing procedure on test items of an object 1, monitors test states of the test items, and analyzes test results of the test items according to the test states. The object 1 may be an electronic product including a plurality of electronic components such as IC chipsets, memories, audio or video cards, for example. Each of the test items may be a test of life analysis of each of the electronic components, or a test of materials identification of each of the electronic components, for example. The electronic device 2 further includes a storage system 20, a processor 22, and a display screen 24. The display screen 24 displays images of a state list of the test items during the testing procedure. An example of the state list is shown in FIG. 3A. An arrangement and content of the state list may be configured or changed according to actual requirements.

The management system 200 performs a testing procedure on the test items of the object 1. The testing procedure defines a sequence of steps for testing the test items.

Once the testing procedure on one test item is finished, the management system 200 obtains test states of the finished test item, and records the test states in the state list. The test states are states of the finished test item generated by the testing procedure, and include normal and abnormal. The management system 200 further analyzes whether the finished test item of the object 1 is abnormal (where “abnormal” indicates a failure, or test duration outside a preset duration) according to the test states of the finished test item, and marks an abnormal test item with a time index in the state list.

The storage system 20 may be a memory (e.g., random access memory, flash memory, hard disk drive) of the electronic device 2. The processor 22 executes one or more computerized codes and other applications of the electronic device 2 to provide functions of the management system 200.

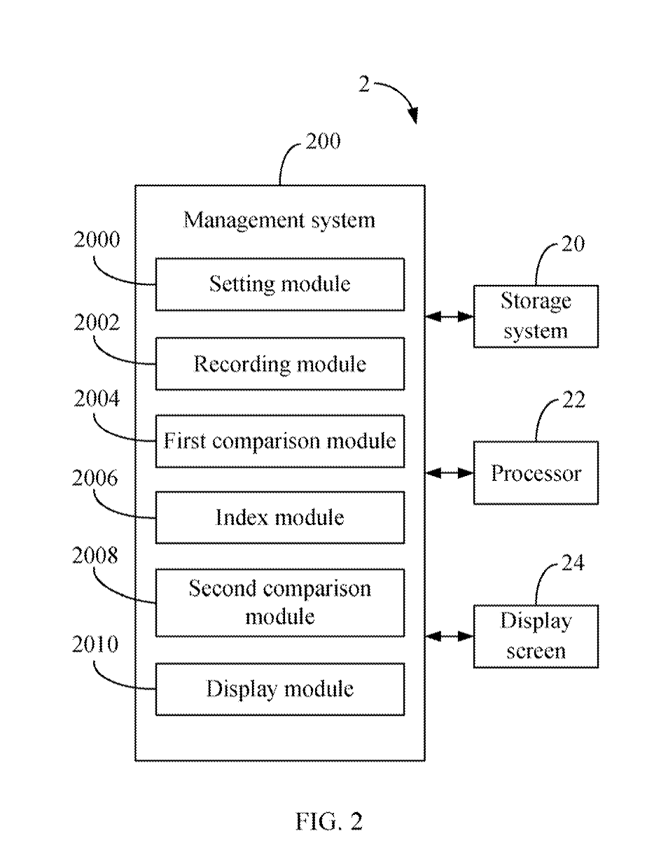

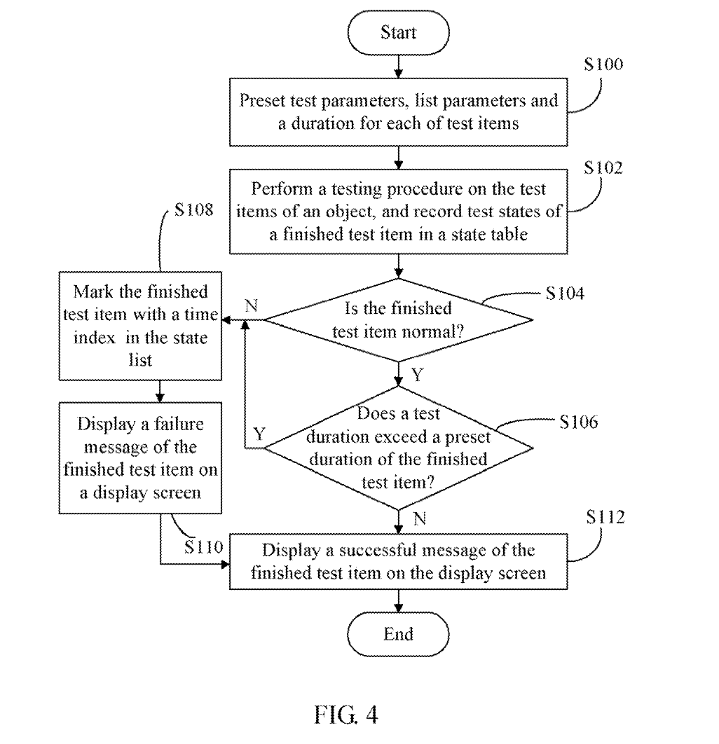

FIG. 2 is a block diagram of one embodiment of function modules of the management system 200 in the electronic device 2. The management system 200 includes a setting module 2000, a recording module 2002, a first comparison module 2004, an index module 2006, a second comparison module 2008, and a display module 2010. The modules 2000, 2002, 2004, 2006, 2008, and 2010 comprise computerized codes in the form of one or more programs that are stored in the storage system 20. The computerized codes include instructions that are executed by the processor 22 to provide functions for the modules. Details of each of the modules are given in FIG. 4.

FIG. 4 is a flowchart illustrating one embodiment of a method for managing test items of an object using the electronic device 2 of FIG. 1. Depending on the embodiment, additional steps may be added, others deleted, and the ordering of the steps may be changed.

In step S100, the setting module 2000 presets test parameters, list parameters and a duration for each of the test items. The test parameters include a plurality of predetermined test items for testing the object 1, for example, “Item 1”, “Item 2” . . . and

“Item 6” shown in FIG. 3B . The list parameters include configurations of the state list, for example, a content of each row shown in FIG. 3B. The preset duration may be different for the test items. The preset duration is a threshold value for determining a test time period of each of the test items.

In step S102, the recording module 2002 perform a testing procedure on the test items of the object 1 according to the test parameters, and records test states of a test item in the state list when the testing procedure on the test item is finished. The testing procedure defines a sequence of steps for testing the test items. The recording module 2002 further stores images of the state list of the finished test item that displayed on the display screen 24 to the storage system 20. The state list includes a plurality of information boxes or cells that store the test states and execution states of the test items. The test states of the finished test item include a test result of the finished test item and test duration of the finished test item. In one embodiment, the recording module 2002 further marks test states of previous finished test items and a test item that has started testing. The recording module 2002 marks the test states by marking the cells in the state list with a preset color or a preset icon.

As shown in FIG. 3B, the first row shows a name of each of the test items (e.g. “Item 1”, “Item 2” . . . and “Item 6” shown in FIG. 3B), and the second row shows a test result of each of the test items that has finished executing. The test result may be success (denoted as “P”) or failure (denoted as “F”). If the test result is success, the test state of the test item is normal. If the test result is failure, the test state of the test item is abnormal.

The third row represents an execution state of each of the test items. The execution state may be finished, executing, or pending execution. The fourth row and the fifth row represent test duration of the finished test item. The fourth row represents a digital number in tens place of the test duration, while the fifth row represents a digital number in ones place of the test duration.

Accordingly, if the recording module 2002 records cells in the state list as shown in FIG. 3A, the state list represents that a test item named “Item 2” has just finished testing, a test result of the “Item 2” being success, and a test duration of the “Item 2” being equal to 47 seconds. Furthermore, according to FIG. 3A, a test result of a previous finished test item named “Item 1” is success, and a subsequent test item named “Item 3” after the “Item 2” has started executing.

In step S104, the first comparison module 2004 obtains a test result of the finished test item by comparing the state list with a standard list stored in the storage system 20, and determines whether the test state of the finished test item is normal according to the obtained test result. If the test result of the finished test item is success, the test state of the finished test item is determined to be normal, and step S106 is implemented. If the test result of the finished test item is failure, the test state of the finished test item is determined to be abnormal, and step S108 is implemented.

In one embodiment, the standard list has the same layout and the same size of cells as the state list, but none of the cells in the standard list are marked. The information in each cell of the standard list is the same type of information as that shown by the state list. Therefore, according to different parts (e.g. marked cells) between the state list and the standard list, the information represented by the different parts (e.g. test result and test duration) can be determined.

In step S106, the second comparison module 2008 obtains the test duration of the finished test item from the state list, and determines whether the test duration exceeds the preset duration of the finished test item. If the test duration exceeds the preset duration of the finished test item, step S108 is implemented. If the test duration does not exceed the preset duration of the finished test item, step S112 is implemented.

In step S108, the index module 2006 marks the finished test item with a time index in the state list. The time index can be obtained according to a system time of the electronic device 2. After the test of the object 1 is finished, images of an abnormal test item can be found from the storage system 20 according to the time index of the abnormal test item. The abnormal test item is the test item that the test state is abnormal, or the test state is normal but the test duration exceeds the preset duration of the test item.

In step S110, the display module 2010 displays a failure message of the finished test item and the name of the finished test item with the time index on the display screen 24.

In step S112, the display module 2010 displays a successful message of the finished test item on the display screen 24.

All of the processes described above may be embodied in, and be fully automated via, functional code modules executed by one or more general-purpose processors. The code modules may be stored in any type of non-transitory computer-readable medium or other storage device. Some or all of the methods may alternatively be embodied in specialized hardware. Depending on the embodiment, the non-transitory computer-readable medium may be a hard disk drive, a compact disc, a digital video disc, a tape drive or other suitable storage medium.

The described embodiments are merely possible examples of implementations, set forth for a clear understanding of the principles of the present disclosure. Many variations and modifications may be made without departing substantially from the spirit and principles of the present disclosure. All such modifications and variations are intended to be included herein within the scope of this disclosure and the described inventive embodiments, and the present disclosure is protected by the following claims.

What is claimed is:

1. A computer-implemented method for managing test items of an object using an electronic device, the method comprising:
performing a testing procedure on the test items of the object, and recording test states of a test item in a state list when the testing procedure on the test item is finished;
obtaining a test result of the finished test item by comparing the state list with a standard list stored in a storage system of the electronic device, and determining whether a test state of the finished test item is normal according to the obtained test result; and
marking the finished test item with a time index in the state list, and displaying a failure message of the finished test item and a name of the finished test item with the time index on a display screen of the electronic device when the test state of the finished test item is abnormal.

2. The method as described in claim 1, further comprising:
obtaining a test duration of the finished test item from the state list, and determining whether the test duration exceeds a preset duration of the finished test item when the test state of the finished test item is normal; and
marking the finished test item with the time index in the state list, and displaying the failure message and the name of the finished test item with the time index on the display screen when the test duration exceeds the preset duration of the finished test item; or
displaying a successful message of the finished test item on the display screen when the test duration does not exceed the preset duration of the finished test item.

3. The method as described in claim 2, wherein the test states of the finished test item comprise the test result of the finished test item and the test duration of the finished test item.

4. The method as described in claim 1, wherein the standard list is the same as the state list except marking any test state.

5. The method as described in claim 1, further comprising:
determining that the test state of the finished test item is normal when the test result is success; or
determining that the test state of the test item is abnormal when the test result is failure.

6. An electronic device for managing test items of an object, the electronic device comprising:
a display screen;
at least one processor; and
a computer-readable storage medium storing one or more programs, which when executed by the at least one processor, causes the at least one processor to:
perform a testing procedure on the test items of the object, and record test states of a test item in a state list when the testing procedure on the test item is finished;
obtain a test result of the finished test item by comparing the state list with a standard list stored in the storage medium, and determine whether a test state of the finished test item is normal according to the obtained test result; and
mark the finished test item with a time index in the state list, and display a failure message of the finished test item and a name of the finished test item with the time index on the display screen when the test state of the finished test item is abnormal.

7. The electronic device as described in claim 6, wherein the one or more programs further comprising causes the at least one processor to:
obtain a test duration of the finished test item from the state list, and determine whether the test duration exceeds a preset duration of the finished test item when the test state of the finished test item is normal; and
mark the finished test item with the time index in the state list, and display the failure message and the name of the finished test item with the time index on the display screen when the test duration exceeds the preset duration of the finished test item; or
display a successful message of the finished test item on the display screen when the test duration does not exceed the preset duration of the finished test item.

8. The electronic device as described in claim 7, wherein the test states of the finished test item comprise the test result of the finished test item and the test duration of the finished test item.

9. The electronic device as described in claim 6, wherein the standard list is the same as the state list except marking any test state.

10. The electronic device as described in claim 6, wherein the one or more programs further comprising causes the at least one processor to:
determine that the test state of the finished test item is normal when the test result is success; or
determine that the test state of the test item is abnormal when the test result is failure.

11. A non-transitory computer readable storage medium having stored thereon instructions that, when executed by a processor of an electronic device, causes the electronic device to perform a method for managing test items of an object, the method comprising:
performing a testing procedure on the test items of the object, and recording test states of a test item in a state list when the testing procedure on the test item is finished;
obtaining a test result of the finished test item by comparing the state list with a standard list stored in a storage system of the electronic device, and determining whether a test state of the finished test item is normal according to the obtained test result; and
marking the finished test item with a time index in the state list, and displaying a failure message of the finished test item and a name of the finished test item with the time index on a display screen of the electronic device when the test state of the finished test item is abnormal.

12. The non-transitory computer readable storage medium as described in claim 11, the method further comprising:
obtaining a test duration of the finished test item from the state list, and determining whether the test duration exceeds a preset duration of the finished test item when the test state of the finished test item is normal; and
marking the finished test item with the time index in the state list, and displaying the failure message and the name of the finished test item with the time index on the display screen when the test duration exceeds the preset duration of the finished test item; or displaying a successful message of the finished test item on the display screen when the test duration does not exceed the preset duration of the finished test item.

13. The non-transitory computer readable storage medium as described in claim 12, wherein the test states of the finished test item comprise the test result of the finished test item and the test duration of the finished test item.

14. The non-transitory computer readable storage medium as described in claim 11, wherein the standard list is the same as the state list except marking any test state.

15. The non-transitory computer readable storage medium as described in claim 11, the method further comprising:
determining that the test state of the finished test item is normal when the test result is success; or
determining that the test state of the test item is abnormal when the test result is failure.
